(19) United States
(12) Patent Application Publication
(10) Pub. No.: US 2009/0134901 A1
(43) Pub. Date: May 28, 2009

(54) INTEGRATED CIRCUIT DIE STRUCTURE SIMPLIFYING IC TESTING AND TESTING METHOD THEREOF

(76) Inventors: Ping-Po Chen, Tainan County (TW); Chien-Pin Chen, Hsinchu (TW)

Correspondence Address: NORTH AMERICA INTELLECTUAL PROPERTY CORPORATION, P.O. BOX 506, MERRIFIELD, VA, 22116, US

(21) Appl. No.: 11/946,053

(22) Filed: Nov. 28, 2007

(51) Int. Cl. G01R 31/26; H01L 23/58

(52) U.S. Cl. 324/765; 257/48; 257/E23.002

(57) ABSTRACT

By adding multiplexing units to selectively transmit signals associated with a functional circuitry of an IC die to test pads, a probe card with less pin counts than the pad number of the IC die can be utilized for testing the functional circuitry. Therefore, the pad number/pad pitch of the IC die is not limited by the pitch of the conventional probe card. A high pin count IC die design is thereby available.

### BACKGROUND OF THE INVENTION

1. Field of the Invention

The present invention relates to an integrated circuit die structure, and more particularly, to an integrated circuit die structure able to simplify chip testing, and a testing method thereof.

2. Description of the Prior Art

As functionality becomes more complex and thinner and smaller sizes become available, an integrated circuit (IC) die is required to have plenty of pads and a small pad pitch. Although a current number of pads is approximately 1440 and the pad pitch has reduced to 15 μm, the current trend is still towards increasing pad numbers and reducing pad pitch. A limitation of the IC design is the probe card used in wafer testing. Since a conventional chip testing technique cannot provide high pin counts/small pitch probe card with low cost, the IC die structure is restricted and the IC designer has to make a choice between performance and production cost.

### SUMMARY OF THE INVENTION

One objective of the present invention is therefore to provide an IC die structure able to simplify chip testing, and a testing method thereof. The IC die structure allows a probe card with pin counts less than the pad number of the IC die to be utilized when chip testing, thereby achieving an advantage of reduced costs. Moreover, the pad number/pad pitch of the IC die is not limited by the pitch of the conventional probe card. A high pin count IC die design is thereby available.

According to an exemplary embodiment of the present invention, an IC die having a functional circuitry formed over a substrate is disclosed. The IC die comprises a first bonding pad for receiving a first signal associated with the functional circuitry, a second bonding pad for receiving a second signal associated with the functional circuitry, at least one test pad for testing the functional circuitry, and a multiplexing unit coupled to the first and the second bonding pads and the test pad, for selectively conducting one of the first and second bonding pads to the test pad.

According to another exemplary embodiment of the present invention, an IC die having a functional circuitry formed over a substrate is disclosed. The IC die comprises a bonding pad for receiving signals associated with the functional circuitry, a test pad for testing the functional circuitry and receiving signals associated with the functional circuitry, and a multiplexing unit coupled to the bonding pad and the test pad, for receiving a first signal and a second signal associated with the functional circuitry and selectively transmitting one of the first and the second signals to the bonding pad or the test pad.

According to another exemplary embodiment of the present invention, a testing method for testing an IC die having a functional circuitry is disclosed. The testing method comprises providing a first bonding pad receiving a first signal associated with the functional circuitry, providing a second bonding pad receiving a second signal associated with the functional circuitry, and selectively conducting one of the first and the second bonding pads to a test pad.

According to another exemplary embodiment of the present invention, a testing method for testing an IC die having a functional circuitry is disclosed. The testing method comprises receiving a first signal and a second signal associated with the functional circuitry, and selectively transmitting one of the first and the second signals to a bonding pad or a test pad.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an IC die according to an exemplary embodiment of the present invention.

FIG. 2 is a diagram of an IC die according to another exemplary embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

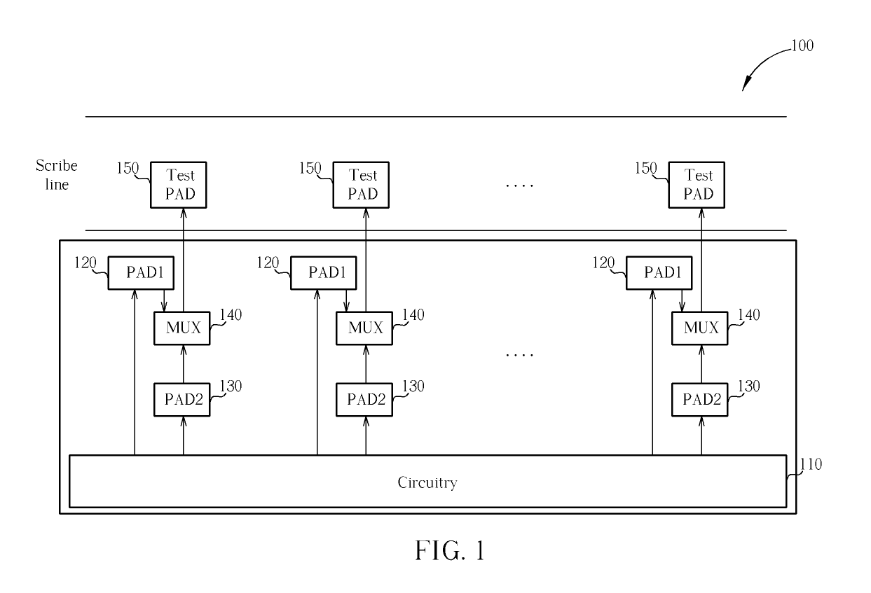

The present invention provides an IC die that can utilize less test pads than conventional IC dies, thereby allowing utilization of a probe card having larger pitch than the pad pitch of the IC die. In one embodiment, a plurality of bonding pads of the IC die jointly share one test pad. FIG. 1 is a diagram of an IC die 100 according to an exemplary embodiment of the present invention. The IC die 100 includes a functional circuitry 110 formed over a substrate, a plurality of first bonding pads 120, a plurality of second bonding pads 130, a plurality of multiplexing units 140, and a plurality of test pads 150. Each first bonding pad 120 is for receiving a first signal associated with the functional circuitry 110, while each second bonding pad 130 is for receiving a second signal associated with the functional circuitry 110. The inputs of each multiplexing unit 140 are respectively coupled to the first bonding pad 120 and the second bonding pad 130, and the output is coupled to a test pad 150, which is disposed as a test probing position. The multiplexing unit 140 selectively conducts one of the first bonding pad 120 and the second bonding pad 130 to the test pad 150.

Each multiplexing unit 140 comprises a control pin (not shown), controlling whether the multiplexing unit 140 operates in a test mode or a normal mode. When operating in the test mode, the multiplexing units 140 alternately transmit the first and the second signals to the test pads 150. In a time slot, the multiplexing units 140 pass the first signals from the first bonding pads 120 to the test pads 150 for a probe card to test. In a next time slot, the multiplexing units 140 pass the second signals from the second bonding pads 120 to the test pads 150 for the probe card to test. Therefore, the probe card used to test the IC die 100 does not need to have same pin counts as the IC die 100, and can have a larger pitch. In this embodiment, the probe card can have half the pin counts of the IC die 100, and double the pitch of the IC die 100. Moreover, in another embodiment, the multiplexing units 140 are not limited to conduct all first signals/second signals at the same time. Some multiplexing units 140 may conduct the first signals to the test pads 150, and others may conduct the second signals to the test pads 150 in a time slot, as long as the multiplexing units conduct other signal in the following time slot.

After the functional circuitry 110 is tested, the multiplexing units 140 are controlled to return to the normal mode, i.e. the multiplexing units 140 are set to be inactive. The first and second signals are not influenced by the status of the multiplexing units 140. The first and second signals are still output through the first bonding pads 120 and the second bonding pads 130 in the normal mode.

In FIG. 1, a 2-pad stack structure is implemented, the multiplexing units 140 are disposed over the IC die 100, and the test pads 150 are disposed over a scribe line adjacent to the IC die 100. The present invention, however, is not limited by the number of the bonding pads/test pads and the position arrangement shown in FIG. 1. The multiplexing units 140 may have more than two inputs or more than one output to extend the IC die 100 to have a 3-pad stack structure, a 4-pad stack structure and so on. Furthermore, the test pads 150 can be disposed over the IC die 100, and the multiplexing units 140 can be disposed over a scribe line adjacent to the IC die 100. The test pads 150 or the multiplexing units 140 disposed over the scribe line are cleaned away automatically in the die sorting process.

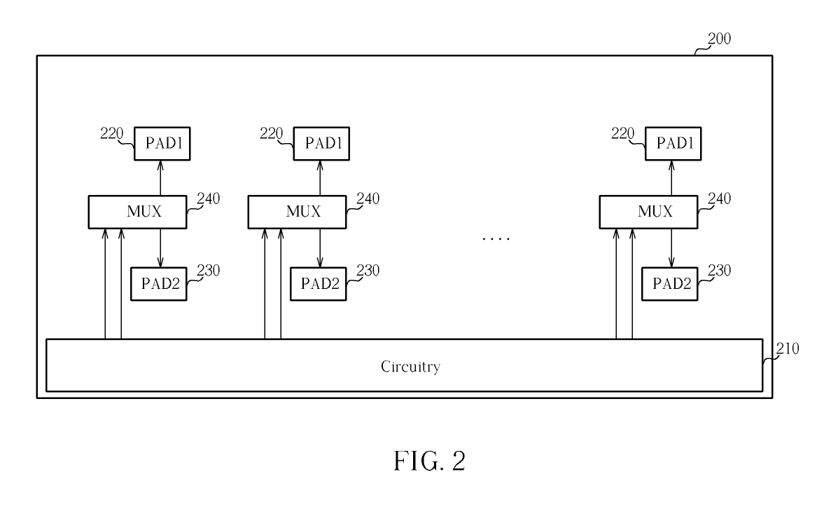

FIG. 2 shows a diagram of an IC die 200 according to another exemplary embodiment of the present invention. The IC die 200 includes a functional circuitry 210, a plurality of bonding pads 220 and 230 for receiving signals associated with the functional circuitry 210, and a plurality of multiplexing units coupled to the bonding pads 220 and 230. Each multiplexing unit 140 receives a first signal and a second signal associated with the functional circuitry 210, and includes a control pin (not shown) for controlling whether the multiplexing unit 140 operates in a test mode or a normal mode.

Part of the bonding pads (for example, the bonding pads 230) is utilized as testing pads in the test mode. The multiplexing units 240 alternately transmit the first and the second signals to the test pad 230 when operating in the test mode, and a probe card conducts its pins to the test pads 230 for testing the functional circuitry 210. Therefore, the probe card used to test the IC die 200 can have half the pin counts of the IC die 200, and double the pitch. As mentioned above, the multiplexing units 240 are not limited to conduct all first/second signals at the same time. Some multiplexing units 240 may conduct the first signals to the test pads 230, and others may conduct the second signals to the test pads 230 in one time slot, as long as the multiplexing units 240 conduct other signal in the following time slot.

As mentioned above, although a 2-pad stack structure is shown in FIG. 2, the multiplexing units 240 may have more than two inputs or more than two outputs to extend the IC die 100 to have a 3-pad stack structure, a 4-pad stack structure and so on.

Please note that the bonding pads 220, and even combinations of part bonding pads 220 and part bonding pads 230 can be utilized as the testing pads. After the chip testing is complete, however, the test pads are utilized as output pads again. When operating in the normal mode, the multiplexing units 240 are controlled by the control pin to respectively transmit the first and the second signals to the bonding pads 220 and the test pads 230.

Compared with the IC die 100 shown in FIG. 1, the pad number of the IC die 200 is decreased since bonding pads in the IC die 200 can be in charge of the function of the test pads 150. Furthermore, the IC die 200 is provided with the following advantages due to the multiplexing units 240, the bonding pads 220 and the testing pads 230 being disposed over the IC die 200: the IC die 200 is more easy to implement because the testing line is inside the IC die 200, and the peeling short problem that test pads/multiplexing units may be residual over the scribe line after die sorting process is not an issue for the IC die 200.

To conclude, the above embodiments add the multiplexing units and test pads, wherein the test pads can be additional pads added for chip testing or original bonding pads in the IC die. By utilizing multiplexing units to selectively transmit signals associated with a functional circuitry of the IC die to test pads, a probe card with pin counts less than the pad number of the IC die can be utilized for testing the functional circuitry. Therefore, the pad number/pad pitch of the IC die is not limited by the pitch of the conventional probe card. A high pin count IC die design is thereby available.

Those skilled in the art will readily observe that numerous modifications and alterations of the device and method may be made while retaining the teachings of the invention.

What is claimed is:

1. An integrated circuit (IC) die having a functional circuitry formed over a substrate, comprising:
a first bonding pad for receiving a first signal associated with the functional circuitry;
a second bonding pad for receiving a second signal associated with the functional circuitry;
at least one test pad for testing the functional circuitry; and
a multiplexing unit coupled to the first and the second bonding pads and the test pad, for selectively conducting one of the first and second bonding pads to the test pad.

2. The IC die of claim 1, wherein the test pad is disposed over a scribe line adjacent to the IC die.

3. The IC die of claim 1, wherein the test pad is disposed over the IC die.

4. The IC die of claim 1, wherein the multiplexing unit is disposed over a scribe line adjacent to the IC die.

5. The IC die of claim 1, wherein the multiplexing unit is disposed over the IC die.

6. The IC die of claim 1, wherein the multiplexing unit further comprises a control pin for controlling whether the multiplexing unit operates in a test mode or a normal mode.

7. The IC die of claim 6, wherein when operating in the test mode, the multiplexing unit alternately conducts the first and the second bonding pads to the test pad.

8. The IC die of claim 6, wherein when operating in the normal mode, the multiplexing unit is inactive.

9. An integrated circuit (IC) die having a functional circuitry, comprising:
a bonding pad for receiving signals associated with the functional circuitry;
a test pad for testing the functional circuitry and receiving signals associated with the functional circuitry; and
a multiplexing unit coupled to the bonding pad and the test pad, for receiving a first signal and a second signal associated with the functional circuitry and selectively transmitting one of the first and the second signals to the bonding pad or the test pad.

10. The IC die of claim 9, wherein the multiplexing unit is disposed over the IC die.

11. The IC die of claim 9, wherein the bonding pad and the test pad are disposed over the IC die.

12. The IC die of claim 9, wherein the multiplexing unit further comprises a control pin for controlling whether the multiplexing unit operates in a test mode or a normal mode.

13. The IC die of claim 12, wherein when operating in the test mode, the multiplexing unit alternately transmits the first and the second signals to the test pad.

14. The IC die of claim 12, wherein when operating in the normal mode, the multiplexing unit respectively transmits the first and the second signals to the bonding pad and the test pad.

15. A testing method for testing an IC die having a functional circuitry, comprising:
a first bonding pad receiving a first signal associated with the functional circuitry;
a second bonding pad receiving a second signal associated with the functional circuitry; and
selectively conducting one of the first and the second bonding pads to a test pad.

16. The testing method of claim 15, further comprising:
determining whether the functional circuitry operates in a test mode or a normal mode.

17. The testing method of claim 16, wherein the step of selectively conducting one of the first and the second bonding pads to the test pad comprises:
alternately conducting the first and the second bonding pads to the test pad when the functional circuitry operates in the test mode.

18. A testing method for testing an IC die have a functional circuitry, comprising:
receiving a first signal and a second signal associated with the functional circuitry; and
selectively transmitting one of the first and the second signals to a bonding pad or a test pad.

19. The testing method of claim 18, further comprising: determining whether the functional circuitry operates in a test mode or a normal mode.

20. The testing method of claim 19, wherein the step of selectively transmitting one of the first and the second signals to the bonding pad or the test pad comprises:
alternately transmitting the first and the second signals to the test pad when the functional circuitry operates in the test mode.

21. The testing method of claim 19, wherein the step of selectively transmitting one of the first and the second signals to the bonding pad or the test pad comprises:
respectively transmitting the first and the second signals to the bonding pad and the test pad when the functional circuitry operates in the normal mode.
